(19) United States
(12) Patent Application Publication
(10) Pub. No.: US 2014/0311548 A1
(43) Pub. Date: Oct. 23, 2014

(54) SOLAR CELL MODULE

(71) Applicant: LG INNOTEK CO., LTD., Seoul (KR)

(72) Inventor: Bong Seok Moon, Seoul (KR)

(73) Assignee: LG INNOTEK CO., LTD, Seoul (KR)

(21) Appl. No.: 14/357,713

(22) PCT Filed: Nov. 9, 2012
(86) PCT No.: PCT/KR2012/009441

§ 371 Date: May 12, 2014

(30) Foreign Application Priority Data
Nov. 10, 2011 (KR) 10-2011-0117236

(51) Int. Cl. H01L 31/02

(52) U.S. Cl. CPC H01L 31/0201
USPC 136/244

(57) ABSTRACT

A solar cell module according to an embodiment includes a support substrate; a solar cell on the support substrate; and a bus bar on the solar cell, wherein the bus bar is prepared as a plurality of rods.

### TECHNICAL FIELD

The embodiment relates to a solar cell module, and more particularly, to a solar cell module capable of representing improved photoelectric conversion efficiency.

### BACKGROUND ART

Recently, as the lack of an energy resource such as petroleum or coal is expected, the interest of the substitute energy have been more increased. In this regard, a solar cell converting solar energy into electric energy is spotlighted.

In particular, a CIGS-based solar cell apparatus, which is a PN hetero junction apparatus having a substrate structure including a glass substrate, a metallic back electrode layer, a P type CIGS-based light absorbing layer, a high-resistance buffer layer, and an N type window layer, has been extensively used.

To transmit a signal of an upper electrode after forming the solar cell, a bus bar is provided between an upper electrode and a junction box of the solar cell.

### DISCLOSURE OF INVENTION

### Technical Problem

The embodiment provides a solar cell module in which productivity of the solar cell module can be improved.

### Solution to Problem

According to the embodiment, there is provided a solar cell module including: a support substrate; a solar cell on the support substrate; and a bus bar on the solar cell, wherein the bus bar is prepared as a plurality of rods.

### Advantageous Effects of Invention

According to the solar cell module of the embodiment, flow of a current becomes smooth by increasing a surface area of a bus bar so that an installation width of the bus bar can be reduced.

Since the installation area of the bus bar is reduced, a light absorbing region can be increased proportionally to the reduction in the installation area of the bus bar.

### BRIEF DESCRIPTION OF DRAWINGS

FIG. 1 is an exploded perspective view showing a solar cell module according to the embodiment.

FIG. 2 is a plan view showing a solar cell module according to the embodiment.

FIG. 3 is a sectional view taken along line A-A′ of FIG. 2.

### BEST MODE FOR CARRYING OUT THE INVENTION

In the description of the embodiments, it will be understood that when a panel, a bar, a frame, a substrate, a groove, or a film, is referred to as being on or under another panel, another bar, another frame, another substrate, another groove, or another film, it can be directly or indirectly on the other panel, the other bar, the other frame, the other substrate, the other groove, the other film, or one or more intervening layers may also be present. Such a position of the layer has been described with reference to the drawings. The size of the elements shown in the drawings may be exaggerated for the purpose of explanation and may not utterly reflect the actual size.

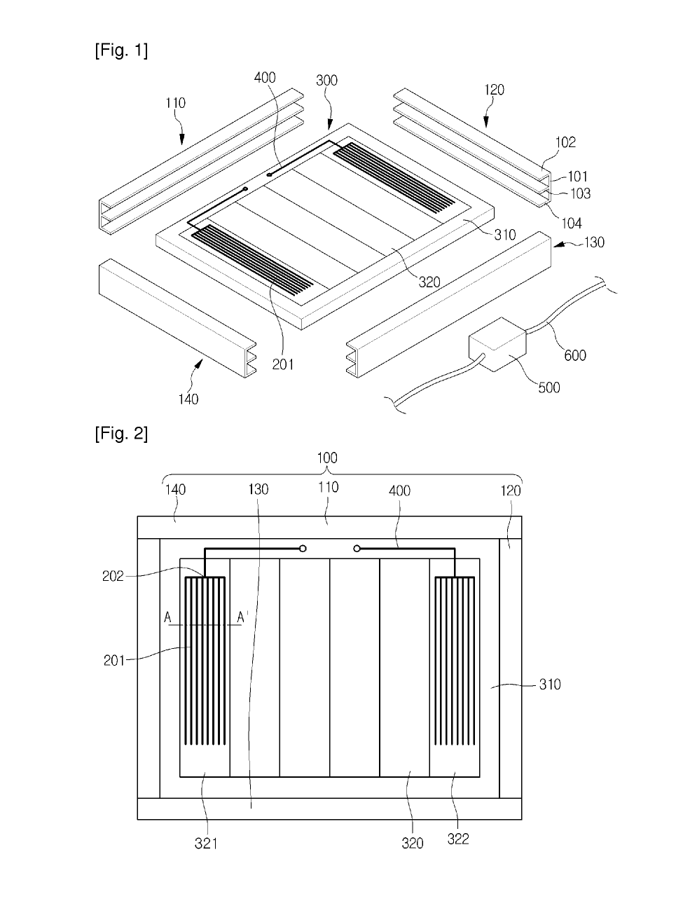

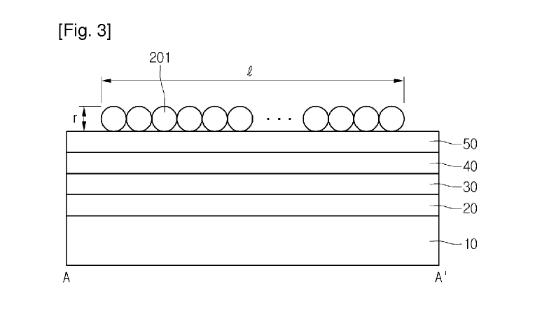

FIG. 1 is an exploded perspective view showing a solar cell module according to the embodiment. FIG. 2 is a plan view showing a solar cell module according to the embodiment. FIG. 3 is a sectional view taken along line A-A′ of FIG. 2.

Referring to FIGS. 1 to 3, the solar cell module according to the embodiment includes a solar cell panel 300, a frame 100 for receiving the solar cell panel 300, a bus bar 400, a junction box 500, and a cable 600.

The frame 100 receives the solar cell panel 300. In detail, the frame 100 surrounds a side of the solar cell panel 300. For example, the frame 100 may be disposed at fourth sides of the solar cell panel 300, respectively.

For example, a material used for the frame 100 may include metal such aluminum. The frame 100 includes a first sub-frame 110, a second sub-frame 120, a third sub-frame 130, and a fourth sub-frame 140. The first sub-frame 110, the second sub-frame 120, the third sub-frame 130, and the fourth sub-frame 140 may be locked with each other.

The first sub-frame 110 surrounds a first side of the solar cell panel 300. The second sub-frame 120 receives a second side of the solar cell panel 300. The third sub-frame 130 faces the first sub-frame 110 while being interposed the solar cell panel 300 therebetween. The third sub-frame 130 receives a third side of the solar cell panel 300. The fourth sub-frame 140 receives a fourth side of the solar cell panel 300. The fourth sub-frame 140 faces the second sub-frame 120 while being interposed the solar cell panel 300 therebetween.

The first sub-frame 110, the second sub-frame 120, the third sub-frame 130, and the fourth sub-frame 140 have a similar structure. That is, the first sub-frame 110, the second sub-frame 120, the third sub-frame 130, and the fourth sub-frame 140 include support parts for receiving the solar cell panel 300.

For example, the first sub-frame 110, the second sub-frame 120, the third sub-frame 130, and the fourth sub-frame 140 include a first support portion 101, a second support portion 102, a third support portion 103, and a fourth support portion 104.

The first support part 101 is disposed at a side of the solar cell panel 300. The first support portion 101 supports the side of the solar cell panel 300.

The second support portion 102 extends from the first support portion 101 and is disposed on a top surface of the solar cell panel 300. The second support portion 102 supports the top surface of the solar cell panel 300.

The third support portion 103 extends from the first support portion 101 and is disposed on a bottom surface of the solar cell panel 300. The third support portion 103 supports the bottom surface of the solar cell panel 300.

The fourth support portion 140 extends from the first support portion 101 and is disposed below the third support portion 103.

Heat generated from the solar cell panel 300 may be efficiently dissipated through the third support portion 103 and the fourth support portion 104.

The first support portion 101, the second support portion 102, the third support portion 104, and the fourth support portion 104 are integrally formed.

The solar cell panel 300 has a plate shape. For example, the solar cell panel 300 may have a square plate shape. The solar cell panel 300 is disposed at an inner side of the frame 100. In detail, an outer peripheral region of the solar cell panel 300 is disposed at the inner side of the frame 100. That is, four sides of the solar cell panel 300 are disposed at the inner side of the frame 100.

The solar cell panel 300 receives solar light and converts the solar light into electric energy. The solar cell panel 300 includes a support substrate 310 and a plurality of solar cells 320. A protective layer for protecting the solar cell panel 300 and an upper substrate disposed on the protective layer in a light receiving surface side of the solar cell panel 300 are formed at an upper portion of the solar cell panel 300, and these components are integrally formed with each other through a lamination process.

The upper substrate and the support substrate 310 protect the solar cell panel 300 from an external environment by preventing moisture from being infiltrated from top and bottom surfaces of the solar cell module. The upper substrate and the support substrate 310 may have a multi-layer structure including a layer for preventing moisture and oxygen from being infiltrated, a layer for preventing chemical corrosion, and a layer having insulation characteristics.

The protective layer is integrated with the solar cell 300 through a lamination process in a state that is disposed at an upper portion of the solar cell panel 300, and prevents corrosion due to infiltration of moisture and protects the solar cell panel 300 from impact. The protective layer may include a material such as ethylene vinyl acetate (EVA). The protective layer may be further formed at a lower portion of the solar cell panel 300.

An upper substrate may be formed on the protective layer. The upper substrate include tempered glass representing high transmittance rate and a superior damage preventing function. In this case, the tempered glass may include low-iron tempered glass. To improve a scattering effect of light, an inner side of the upper substrate may be embossed.

The bus bar 400 is connected to the solar cell panel 300. In detail, the bus bar 400 is disposed on top surfaces of outermost solar cells 320. The bus bar 400 makes direct contact with the top surfaces of the outermost solar cells 320 to be connected to the solar cells 320.

The solar cells 320 may include a back electrode layer 20, a light absorbing layer 300, a buffer layer 40, and an upper electrode layer 50 formed on a substrate.

A hole is formed at a partial region of the support substrate 310 so that the bus bar 400 may be connected to the cable 600 through the hole.

The bus bar 400 may make contact with both ends of the solar cells 320. That is, based on the drawing, a right panel 322 may be electrically connected to a left panel 321. The bus bar 400 moves a signal of an electrode generated from a solar cell to a junction box 500. If an area of the bus bar 400 is increased, flow of a current may become smooth, but a light absorbing region of the light absorbing layer 30 is reduced due to the increase of the area of the bus bar 400 so that photoelectric conversion efficiency may be reduced. If a surface area of the bus bar 400 is increased, a current flowing through the bus bar 400 may be increased.

Although an existing bus bar 400 has a plate shape, most of the current flows through a surface of the bus bar due to a skin effect. In consideration of this, the bus bar 400 according to the embodiment has a thin rod shape, and a plurality of bus bars may be connected to each other in parallel. When the bus bar 400 has a plurality of rods, the bus bars may make contact with or be spaced apart from each other.

When the bus bars are spaced apart from each other, because a predetermined part of light incident to the solar cell may be incident to the light absorbing layer 30 between the bus bars 40, the photoelectric conversion efficiency may be improved.

The bus bar 40 may be formed by depositing one of silver (Ag), copper (Cu), gold (Au), aluminum (Al), tin (Sn), and nickel (Ni) or an alloy thereof through a sputtering process.

The bus bar 400 may include a plurality of bus bar, and may have a circular section.

The bus bars branch at a branch region 202, a diameter r of each bus bar may be in the range of 0.01 mm to 0.05 mm, and a length 1 of each bus bar may be in the range of 2 mm to 6 mm.

A process for the upper electrode layer 50 and the bus bar 400 may be performed in a vacuum chamber and the same chamber. In this case, since the bus bar 400 is formed in the vacuum chamber, serial resistance with the upper electrode 50 is reduced so that an electric conductivity of the bus bar 400 may be improved.

The upper electrode layer 50 is doped with aluminum so that an adhesive force between the bus bar 400 and the front electrode 600 including a metallic material may be reinforced.

That is, the same metallic material as the aluminum doped in the upper electrode layer 50 is used so that a coupling force between the upper electrode layer 50 and the bus bar 400 may be improved.

The junction box 500 is disposed below the solar cell panel 300. The junction box 500 may adhere to a bottom surface of the solar cell panel 300. The junction box 500 includes a diode, and may receive a circuit board which is connected to the bus bar 400 and the cable 600.

The solar cell module according to the embodiment may further include a wire for connecting the bus bar 400 to the circuit board. The cable 600 is connected to the circuit board and another solar cell panel 300.

Any reference in this specification to one embodiment, an embodiment, example embodiment, etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effects such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell module comprising:
a support substrate;
a plurality solar cells on the support substrate; and
a bus bar on the plurality solar cells,
wherein the bus bar is prepared as a plurality of rods.

2. The solar cell module of claim 1, each of the rods has a diameter in a range of 0.01 mm to 0.05 mm.

3. The solar cell module of claim 1, wherein a length of a bus bar prepared in a form of the rods is in a range of 2 mm to 6 mm.

4. The solar cell module of claim 1, wherein the bus bar comprises at least one of silver (Ag), copper (Cu), gold (Au), aluminum (Al), tin (Sn), and nickel (Ni).

5. The solar cell module of claim 1, wherein the bus bar is provided at a solar cell which is formed on an outer peripheral region of the support substrate.

6. The solar cell module of claim 1, wherein the rods are connected to each other in parallel, and adjacent rods are spaced apart from each other.

7-14. (canceled)

15. The solar cell module of claim 1, wherein the bus bars are disposed on top surfaces of outermost solar cells.

16. The solar cell module of claim 1, further comprising a hole is formed at a partial region of a support substrate.

17. The solar cell module of claim 1, wherein the rods are adjacent rods are contact from each other.

18. The solar cell module of claim 1, wherein the bus bar formed at a partial region of the support substrate.
